(19) United States
(12) Patent Application Publication
(10) Pub. No.: US 2026/0088623 A1
(43) Pub. Date: Mar. 26, 2026

(54) ENERGY STORAGE UNIT, ENERGY STORAGE SYSTEM, AND ELECTRIC ENERGY STORAGE AND CONVERSION SYSTEM

(71) Applicant: GS Yuasa International Ltd., Kyoto (JP)

(72) Inventors: Tsutomu UENO, Kyoto (JP); Hirokazu ITO, Kyoto (JP); Tomoshige INOUE, Kyoto (JP); Masakatsu KURISAKA, Kyoto (JP)

(21) Appl. No.: 19/121,364

(22) PCT Filed: Sep. 15, 2023
(86) PCT No.: PCT/JP2023/033704

§ 371 Date: Apr. 15, 2025

(30) Foreign Application Priority Data
Oct. 17, 2022 (JP) 2022-166214

(51) Int. Cl. H02J 3/32; G01R 31/374; G01R 31/3842; G01R 31/389; G01R 31/396; H01M 10/42; H02J 3/38; H02J 7/02

(52) U.S. Cl. CPC H02J 3/32; G01R 31/374; G01R 31/3842; G01R 31/389; G01R 31/396; H01M 10/425; H02J 3/38; H02J 7/02; H01M 2010/4271

(57) ABSTRACT

Provided is an energy storage unit 15A for an energy storage system, and the energy storage unit includes an energy storage bank 20 which is connected to a power conversion device 10, and a bank management device 50. The bank management device 50 either calculates, on the basis of a current target value Ino and a current measurement value Int of the energy storage bank 20, a current limit value Ilimit to limit an excess of a current I with respect to the current target value Ino, or calculates, on the basis of a power target value Pno and a power measurement value Pnt of the energy storage bank 20, a power limit value Plimit to limit an excess of power with respect to the power target value Pno.

### CROSS REFERENCE TO RELATED APPLICATIONS

This application is a National Stage Application, filed under 35 U.S.C. § 371, of International Application No. PCT/JP2023/033704, filed Sep. 15, 2023, which international application claims priority to and the benefit of Japanese Application No. 2022-166214, filed Oct. 17, 2022; the contents of both of which as are hereby incorporated by reference in their entireties.

### BACKGROUND

### Technical Field

The present invention relates to a technique for controlling a current and power of an energy storage bank.

### Description of Related Art

In recent years, in order to achieve saving of energy, energy storage systems for residential use, industrial use, and energy management use have become widespread. As a document which discloses this type of technique, Patent JP2012-205437 A is presented.

### BRIEF SUMMARY

An energy storage system S1 of FIG. 1 is configured from a plurality of energy storage units 15A to 15C, and an integrated battery management device 100. The plurality of energy storage units 15A to 15C are configured from energy storage banks 20A to 20C and bank management devices 50A to 50C. Each of the energy storage banks 20A to 20C is connected to a grid G via a power conversion device (PCS) 10. It is desirable that currents I1 to I3 of the energy storage banks 20A to 20C should not exceed a current target value of the energy storage banks 20A to 20C. The current target value of the energy storage banks 20A to 20C is a limit value (an upper limit value) of a current I at which the energy storage banks 20A to 20C can be safely operated.

However, in the case of a multiple bank configuration, if there is a difference in temperature or variation in deterioration among the energy storage banks 20A to 20C, the currents may become nonuniform. Therefore, even if an aggregate current IT of the energy storage system S1 is controlled to a current target value of the energy storage system S1, in some of the banks, there is a possibility that the currents I1 to I3 may exceed the current target value of the energy storage banks 20A to 20C.

As illustrated in FIG. 9, even in an energy storage system S2 of a single bank configuration, the current I of the energy storage bank 20 may exceed the current target value of the energy storage bank 20 depending on the conversion efficiency, measurement accuracy, and the like, of the power conversion device 10. The conversion efficiency is the efficiency of conversion from AC to DC. For example, in a case where a current is measured at an AC terminal P1, even if the current is maintained at a target value at the AC end, the current I of the energy storage bank 20 may exceed the current target value of the energy storage bank 20 after conversion from AC to DC depending on the accuracy and variations of the conversion efficiency.

A similar problem is found not only in the case of controlling the current but also in the case of controlling the power of an energy storage bank.

An object of the present invention is to suppress an excess of a current or power of the energy storage bank.

An energy storage unit for an energy storage system includes an energy storage bank which is connected to a power conversion device, and a bank management device. The bank management device either: calculates, on the basis of a current target value and a current measurement value of the energy storage bank, a current limit value to limit an excess of a current with respect to the current target value; or calculates, on the basis of a power target value and a power measurement value of the energy storage bank, a power limit value to limit an excess of power with respect to the power target value.

An energy storage system, which is connected to a power conversion device and stores electric energy, includes a plurality of energy storage units, and an integrated battery management device. The energy storage unit includes an energy storage bank which is connected to the power conversion device, and a bank management device which is provided to correspond to the energy storage bank. The integrated management device either: acquires or calculates a current limit value of each of the energy storage banks from the bank management device, and calculates a current limit value of the energy storage system on the basis of the current limit value of each of the energy storage banks; or acquires or calculates a power limit value of each of the energy storage banks from the bank management device, and calculates a power limit value of the energy storage system on the basis of the power limit value of each of the energy storage banks.

An electric energy storage and conversion system is provided with a power conversion device and the above-described energy storage system. The power conversion device either controls a current of the energy storage system to be less than or equal to the current limit value of the energy storage system, or controls power of the energy storage system to be less than or equal to the power limit value of the energy storage system.

The present technique can also be applied to a method of controlling the energy storage system or the electric energy storage and conversion system.

The present technique is capable of suppressing an excess of the current or an excess of the power of the energy storage bank.

### BRIEF DESCRIPTION OF THE FIGURES

FIG. 1 is a block diagram of a system configuration of an electric energy storage and conversion system.

FIG. 2 is a block diagram of an energy storage unit.

FIG. 3 is a diagram illustrating an energy storage module and a sensor unit.

FIG. 4 is a block diagram illustrating an electrical configuration of an energy storage system.

FIG. 5 is an arithmetic block related to a current limiting function.

FIG. 6 is a graph showing current measurement results.

FIG. 7A is a graph showing current measurement results of energy storage banks.

FIG. 7B is a graph showing a result of measurement of an aggregate current of an energy storage system.

FIG. 8A is a graph showing current simulation results.

FIG. 8B is a graph showing current simulation results.

FIG. 9 is a block diagram of a system configuration of an energy storage system.

### DETAILED DESCRIPTION OF VARIOUS EMBODIMENTS

(1) An energy storage unit for an energy storage system includes an energy storage bank which is connected to a power conversion device, and a bank management device. The bank management device either: calculates, on the basis of a current target value and a current measurement value of the energy storage bank, a current limit value to limit an excess of a current with respect to the current target value; or calculates, on the basis of a power target value and a power measurement value of the energy storage bank, a power limit value to limit an excess of power with respect to the power target value.

With the energy storage unit according to (1), when used in a multiple bank configuration, it is possible to suppress an excess of the current of the energy storage bank with respect to the current target value without dependence on the temperature management of the energy storage bank. When used in a single bank configuration, it is possible to suppress an excess of the current of the energy storage bank with respect to the current target value without dependence on the conversion efficiency and the measurement accuracy of the power conversion device. Consequently, the energy storage unit can be operated safely. The same applies to the case where power is controlled instead of the current.

(2) In the energy storage unit according to (1) described above, the bank management device may either acquire at least the current measurement value at a predetermined cycle and update the current limit value of the energy storage bank, or acquire at least the power measurement value at a predetermined cycle and update the power limit value of the energy storage bank.

With the energy storage unit according to (2), since the current limit value is updated at a predetermined cycle on the basis of the latest current measurement value, it is possible to suppress an excess of the current of the energy storage bank with respect to the current target value without dependence on a change in the current. The same applies to the case where power is controlled instead of the current.

(3) In the energy storage unit according to (1) or (2) described above, the bank management device may either: calculate the current limit value of the energy storage bank on the basis of a difference of the current measurement value from the current target value of the energy storage bank and a ratio of the current measurement value to the current target value; or calculate the power limit value of the energy storage bank on the basis of a difference of the power measurement value from the power target value of the energy storage bank and a ratio of the power measurement value to the power target value.

With the energy storage unit according to (3), when the exceeding current is limited to exhibit the current target value, it is possible to suppress an undershoot of the current so that a smooth response waveform can be realized. The same applies to the case where power is controlled instead of the current.

(4) In the energy storage unit according to any one of (1) to (3) described above, the bank management device may either calculate the current limit value of the energy storage bank, or calculate the power limit value of the energy storage bank from equations which are:

$$Ylimit = Yno + Ysup ; and$$

$$Ysup = ( previous value of Ysup + Yno - Ynt ) \times ( Yno / Ynt ) ,$$

where Ylimit is one of the current limit value and the power limit value of the energy storage bank, Yno is one of the current target value and the power target value of the energy storage bank, Ysup is one of a current suppression value and a power suppression value of the energy storage bank, and Ynt is one of the current measurement value and the power measurement value of the energy storage bank.

With the energy storage unit according to (4), it is possible to calculate the current suppression value and the current limit value by a simple arithmetic computation using a difference between the current target value and the current measurement value and the ratio between the current target value and the current measurement value. The same applies to the case of arithmetically computing the power suppression value and the power limit value instead of the current suppression value and the current limit value.

(5) In the energy storage unit according to any one of (1) to (4) described above, the bank management device may either calculate the current limit value of the energy storage bank, or calculate the power limit value of the energy storage bank from an equation which is:

$$Ylimit = previous value of Ylimit \times ( Yno / Ynt ) ,$$

where Ylimit is one of the current limit value and the power limit value of the energy storage bank, Yno is one of the current target value and the power target value of the energy storage bank, and Ynt is one of the current measurement value and the power measurement value of each of energy storage banks including the energy storage bank.

With the energy storage unit according to (5), it is possible to calculate the current limit value by a simple arithmetic computation using the ratio between the current target value and the current measurement value. As compared to the arithmetic computation method according to (4), there is no need to calculate a difference between the current target value and the current measurement value, and an arithmetic computation load of the bank management device can be reduced. The same applies to the case of arithmetically computing the power limit value instead of the current limit value.

(6) An energy storage system is a system which is connected to a power conversion device and stores electric energy, and includes a plurality of energy storage units, and an integrated battery management device. The energy storage unit includes an energy storage bank which is connected to the power conversion device, and a bank management device which is provided to correspond to the energy storage bank. The integrated management device either: acquires or calculates a current limit value of each of the energy storage banks from the bank management device, and calculates a current limit value of the energy storage system on the basis of the current limit value of each of the energy storage banks; or acquires or calculates a power limit value of each of the energy storage banks from the bank management device, and calculates a power limit value of the energy storage system on the basis of the power limit value of each of the energy storage banks. The energy storage bank may be the energy storage bank according to any one of (1) and (5), or may be an energy storage bank other than the energy storage banks of (1) to (5).

(7) An electric energy storage and conversion system is provided with a power conversion device and the energy storage system according to (6). The power conversion device either controls a current of the energy storage system to be less than or equal to the current limit value, or controls power of the energy storage system to be less than or equal to the power limit value.

With the energy storage system according to (6) and the electric energy storage and conversion system according to (7), it is possible to suppress an excess of the current or an excess of the power of the energy storage bank without dependence on the temperature management of the energy storage bank. This configuration is effective when the energy storage system has a system configuration in which the temperature management cannot be performed sufficiently or when the energy storage system is used in an installation environment in which the temperature management is difficult.

### Embodiment 1

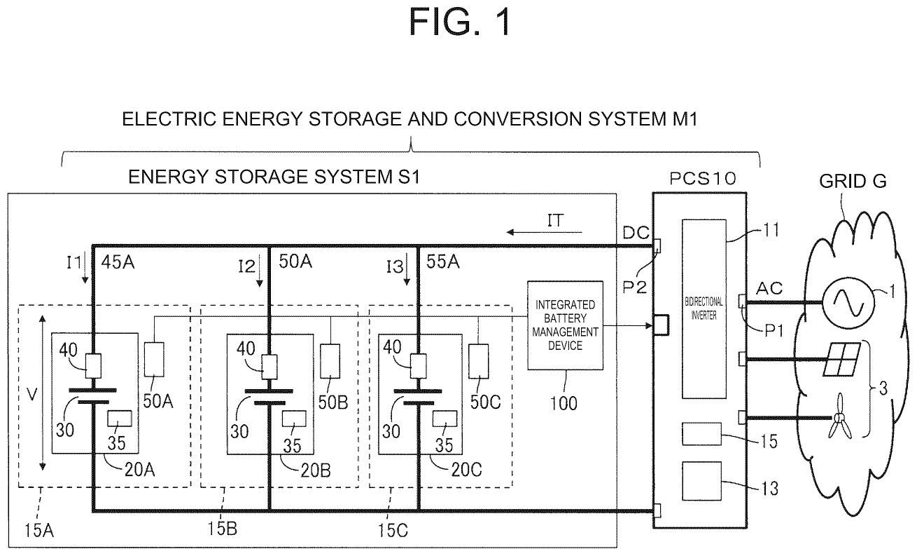

FIG. 1 is a block diagram of an electric energy storage and conversion system M1. The electric energy storage and conversion system M1 is configured from an energy storage system S1 and a power conditioner 10, and is connected to a grid G via the power conditioner 10. The grid G includes a system power supply 1 and a distributed power supply 3, such as a photovoltaic power generation panel and a wind power generator, and supplies AC power at a commercial frequency.

The power conditioner 10 is a bidirectional power conversion device, and includes a bidirectional inverter 11, a control unit 13, and a measurement unit 15. The bidirectional inverter 11 can convert AC power of the grid G into DC power and charge the energy storage system S1. Conversely, the DC power of the energy storage system S1 can be converted into AC power and the converted AC power can be output to the grid G. The measurement unit 15 measures the voltage and the current at an AC terminal P1 or a DC terminal P2 of the power conditioner 10. In the present embodiment, the voltage and the current at the DC terminal P2 are measured.

The energy storage system S1 can be used for various purposes such as residential use, industrial use, and energy management use. The energy storage system S1 stores electricity by surplus power of the grid G, and discharges electricity according to a balance of supply and demand of the power. In this way, the energy storage system S1 can contribute to efficient use of energy.

The energy storage system S1 is configured from a plurality of energy storage units 15A to 15C, and an integrated battery management device 100.

The respective energy storage units 15A to 15C are configured from energy storage banks 20A to 20C and bank management devices 50A to 50C.

The energy storage banks 20A to 20C are connected in parallel to the power conditioner 10. The energy storage banks 20A to 20C have the same configuration.

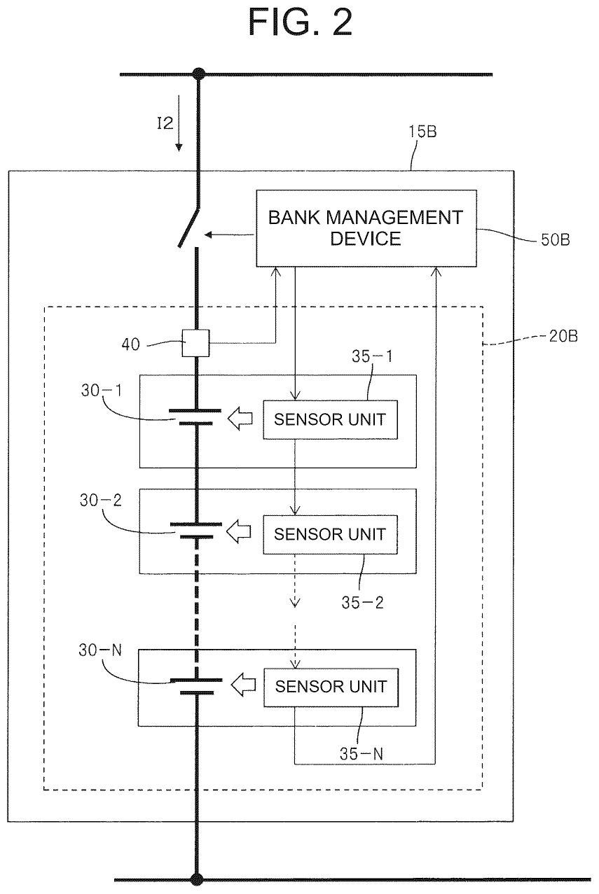

As illustrated in FIG. 2, the energy storage banks 20A to 20C are each configured from a plurality of energy storage modules 30-1, 30-2, and 30-N that are connected in series, a plurality of sensor units 35-1, 35-2, and 35-N, and a current sensor 40. The plurality of energy storage modules are hereinafter collectively referred to as the energy storage module 30. The same applies to the sensor unit 35.

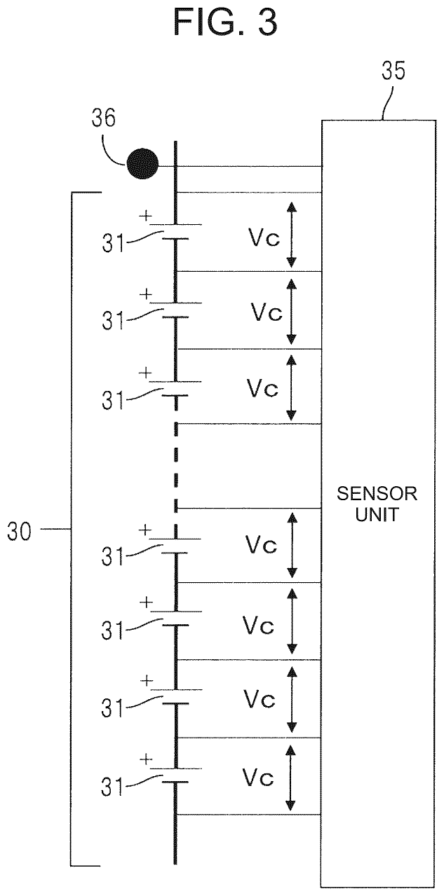

As illustrated in FIG. 3, a single energy storage module 30 is configured from a plurality of energy storage cells 31 that are connected in series. As the energy storage cell 31, a lithium-ion secondary battery cell or the like can be used.

The sensor units 35 are provided for the energy storage modules 30, respectively. The sensor unit 35 detects a cell voltage Vc of each of the energy storage cells 31. The sensor unit 35 includes a temperature sensor 36, and also detects a battery temperature T of the energy storage module 30.

As illustrated in FIG. 2, the sensor unit 35 is communicably connected to the adjacent sensor unit 35. In response to an instruction from the bank management device 50B, the sensor units 35 sequentially transfer data from an upstream sensor unit 35 to a downstream sensor unit 35. In this way, the results of measurement of the respective sensor units 35 can be aggregated in the most downstream sensor unit 35N and transmitted to the bank management device 50B.

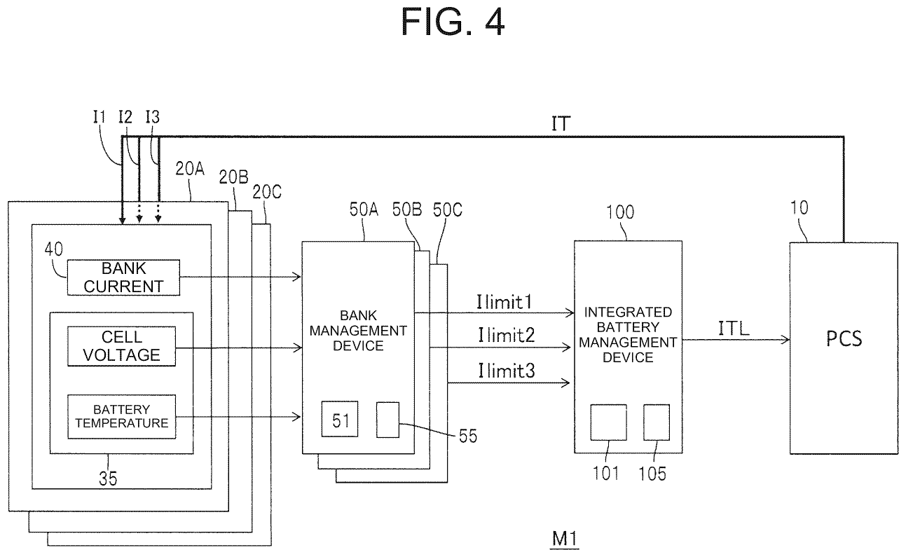

The bank management devices 50A to 50C are provided for the energy storage banks 20A to 20C, respectively. As illustrated in FIG. 4, the bank management devices 50A to 50C are each provided with an arithmetic unit 51 such as a CPU, and a storage unit 55. In the storage unit 55, data necessary for executing a current limiting function, which will be described later, is stored.

The bank management devices 50A to SOC each monitor, on the basis of various kinds of data transmitted from the sensor unit 35 and the current sensor 40, a current I of the energy storage banks 20A to 20C, the cell voltage Vc of each of the energy storage cells 31, and the battery temperature T.

The bank management devices 50A to 50C are communicably connected to the integrated battery management device 100. The integrated battery management device 100 is provided with an arithmetic unit 101 such as a CPU, and a storage unit 105.

The integrated battery management device 100 monitors the state of the system as a whole, on the basis of the monitoring data of the energy storage banks 20A to 20C (i.e., data on the current I of the energy storage bank 20, the cell voltage Vc of each of the energy storage cells 31, and the battery temperature T) transmitted from the bank management devices 50A to 50C.

### 2. Current Limiting Function

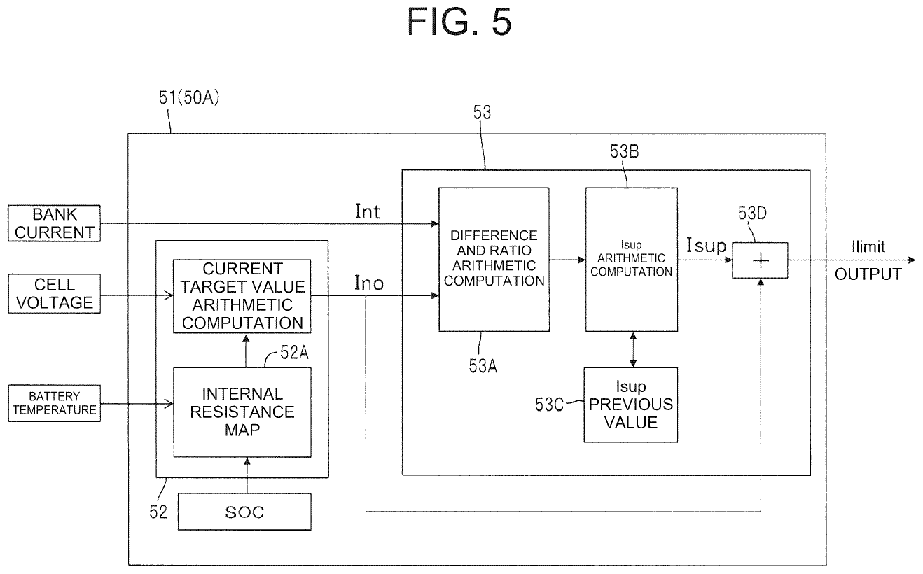

FIG. 5 shows arithmetic blocks related to the current limiting function of the bank management device 50A. The arithmetic unit 51 of the bank management device 50A includes a first arithmetic block 52 and a second arithmetic block 53. The other bank management devices 50B and 50C also have similar arithmetic blocks.

The first arithmetic block 52 includes an internal resistance map 52A and calculates, on the basis of the battery temperature and an SOC of the energy storage bank 20, internal resistance R of the energy storage cell 31. The SOC can be obtained by a current integration method. The SOC indicates the state of charge and can be represented by a ratio of the remaining capacity [Ah] to a full charge capacity [Ah].

The first arithmetic block 52 calculates, on the basis of data on the cell voltage Vc and the internal resistance R of the energy storage cell 31, a current target value Ino of the energy storage bank 20. The current target value Ino is an upper limit value of the current I at which the energy storage bank 20 can be safely operated.

The current target value Ino may either be obtained by, for example, a calculation formula with Vc and R as variables, or by using a reference table for determining the current target value Ino in which Vc and R are applied as input values. In general, the lower the cell voltage Vc is, the higher the current target value Ino is, and the greater the internal resistance R is, the lower the current target value Ino is.

In this example, the current target value Ino during a charge is calculated by using the maximum value of the cell voltage Vc, and the current target value Ino during a discharge is calculated by using the minimum value of the cell voltage Vc. The first arithmetic block 52 may update the current target value Ino on the basis of the data on Vc and R at each point of time.

In a case where the current target value Ino of the energy storage bank 20 is 50A (Ino=50 A), it is considered that the current target value of the energy storage system S1 is set to 150 A (50 A×3). However, even if an aggregate current IT of the energy storage system S1 is controlled to 150 A by the power conditioner 10, if there is a difference in temperature or variation in deterioration among the energy storage banks 20A to 20C, currents I1 to I3 become nonuniform. Thus, in some of the energy storage banks 20A to 20C, there is a possibility that the currents I1 to I3 may exceed the current target value Ino of the energy storage bank 20.

In the example of FIG. 1, although the aggregate current IT of the energy storage system S1 is controlled to 150 A, each of the values of the currents I1 to I3 are I1=45 A, I2=50 A, and I3=55 A, and the current I3 of the energy storage bank 20C exceeds the current target value (Ino=50 A) of the energy storage bank 20.

The second arithmetic block 53 illustrated in FIG. 5 calculates a current suppression value Isup and a current limit value Ilimit of the energy storage bank 20 in order to suppress an excess of the current I of the energy storage bank 20 with respect to the current target value Ino. The current suppression value Isup is an amount of adjustment of the current I (a range of reduction with respect to the present value), and the current limit value Ilimit is a current upper limit value.

To be more specific, the second arithmetic block 53 includes a first arithmetic unit 53A, a second arithmetic unit 53B, a memory 53C, and an addition unit 53D.

The first arithmetic unit 53A calculates, on the basis of the current target value Ino and a current measurement value Int of the energy storage bank 20, a current difference Ino−Int and a current ratio Ino/Int. When there is an excess of the current, since Ino<Int, the following relationships are satisfied: Ino−Int<0 and Ino/Int<1.

The second arithmetic unit 53B arithmetically computes, on the basis of the current difference Ino-Int, the current ratio Ino/Int, and a previous value of the current suppression value Isup that is stored in the memory 53C, the current suppression value Isup. However, the initial value of Isup is zero.

The addition unit 53D adds the current target value Ino and the current suppression value Isup to calculate the current limit value Ilimit. The calculation formulas of Isup and Ilimit are as follows:

$$Isup = ( previous value of Isup + Ino - Int ) \times ( Ino / Int ) ; and \qquad Equation ( A )$$

$$Ilimit = Ino + Isup , \qquad Equation ( B )$$

where
Isup represents the current suppression value of the energy storage bank 20, Ino represents the current target value of the energy storage bank 20, Int represents the current measurement value of the energy storage bank 20, and Ilimit represents the current limit value of the energy storage bank 20. When Isup>0 (i.e., when there is no excess of the current), it is assumed that Isup=0.

An example of the calculation is as described below. In a case where Ino=50 A, Int=55 A, and the previous value of Isup=0, it is calculated that Ino−Int=−5A and Ino/Int=0.9. Thus, Isup and Ilimit are calculated as Isup=−4.5 A and Ilimit=45.5 A.

The bank management devices 50A to 50C acquire data on the current measurement value Int from the current sensor 40 at a predetermined cycle regardless of whether a discharge or a charge is being performed, when the energy storage system S1 is in operation, and arithmetically compute the current difference Ino-Int and the current ratio Ino/Int on the basis of the latest acquired data on the current measurement value Int. The current target value Ino may be calculated each time, or a fixed value may be used.

The bank management devices 50A to 50C recalculate and update, on the basis of the current difference Ino-Int and the current ratio Ino/Int which have been arithmetically computed at a predetermined cycle, the current suppression value Isup and the current limit value Ilimit. The bank management devices 50A to 50C output the updated current limit value Ilimit to the integrated battery management device 100 each time the update is performed.

The integrated battery management device 100 compares the current limit values Ilimit1 to Ilimit3 of the energy storage banks 20A to 20C, which are respectively transmitted from the bank management devices 50A to 50C, with each other, and determines the minimum current limit value Ilimit.

Specifically, as indicated by Equation (C), the following is calculated by multiplying the minimum current limit value Ilimit by the number of banks (the number of parallel connections) N of the energy storage banks 20.

$$ITL = Ilimit \times N \qquad Equation ( C )$$

An example of the calculation is as described below. In a case where Ilimit=45.5 A and N=3, the current limit value ITL of the energy storage system S1 is calculated as 136.5 A (45.5×3).

The integrated battery management device 100 calculates the current limit value ITL of the energy storage system S1 at a predetermined cycle, and transmits the result to the power conditioner 10.

The power conditioner 10 controls the aggregate current IT of the energy storage system S1 to the initial value (the current target value Ino of the energy storage bank 20×the number of banks=150 A) immediately after a start of the control.

After that, the power conditioner 10 controls, on the basis of the current limit value ITL that is output from the integrated battery management device 100, the aggregate current IT of the energy storage system S1 to be less than or equal to the current limit value ITL (the minimum current limit value Ilimit of the energy storage bank 20×bank number N).

Specifically, the aggregate current IT of the energy storage system S1 is controlled to be less than or equal to the current limit value ITL via the bidirectional inverter 11, while the measurement value of the aggregate current IT (the current at the DC terminal P2) obtained by the measurement unit 15 is being referred to.

By controlling the aggregate current IT of the energy storage system S1 to be less than or equal to the current limit value ITL, it is possible to suppress an excess of the currents I1 to I3 with respect to the current target value Ino of the energy storage bank 20 in each of the energy storage banks 20A to 20C.

The update cycle (arithmetic cycle) of updating (arithmetically computing) the current suppression value Isup and the current limit value Ilimit of the energy storage bank 20 should desirably be a cycle that is longer than a current control cycle of the power conditioner 10. By making the update cycle longer, it is possible to prevent the current suppression value and the current limit value from being updated in a state where the current has not been adjusted yet. Therefore, a current suppression function can be effectively performed.

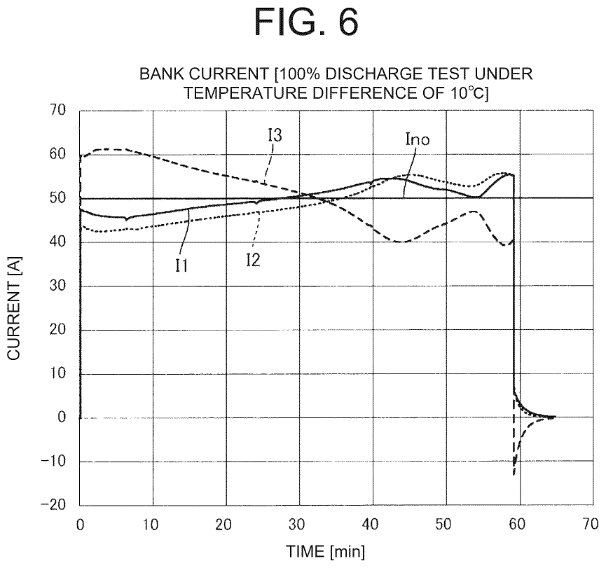

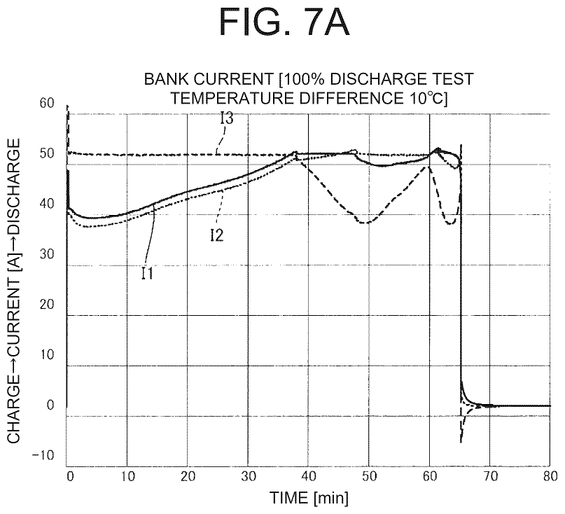

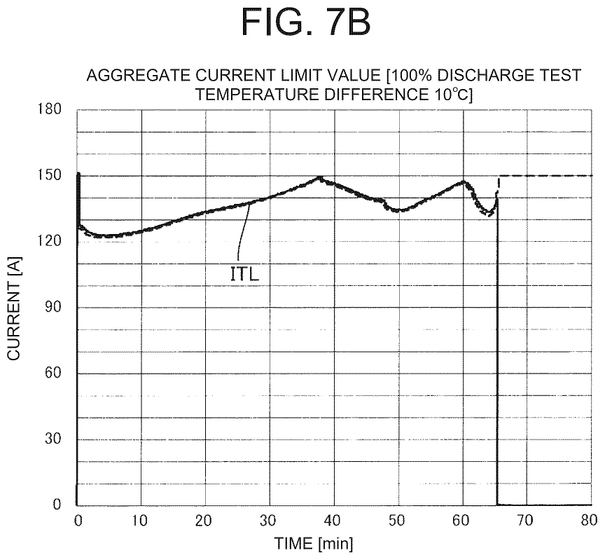

FIGS. 6 and 7 are graphs showing the currents I1 to I3 of the energy storage banks 20A to 20C when a discharge is performed under the condition that there is a difference in temperature between the banks in the energy storage system S1. The temperature of the energy storage bank 20C is higher than that of the energy storage banks 20A and 20B by about 10° C., whereby the energy storage bank 20C is in a condition in which the current I easily flows (the higher the temperature is, the smaller the internal resistance is and the easier the current flows). The current target value Ino of the current I is 50 A.

FIG. 6 is a graph of the case where no current limiting function is performed and the aggregate current IT of the energy storage system S1 is controlled to the initial value of 150 A. For a period of until about 30 seconds have elapsed from the start of discharge, the current I3 of the energy storage bank 20C exceeds the current target value of the energy storage bank 20C, i.e., 50 A. In particular, for about 10 seconds from the start of the discharge, the current I3 is about 60 A and is exceeded by 10 A.

FIG. 7 is a graph of the case where the current limiting function is performed and the aggregate current IT of the energy storage system S1 is limited to exhibit the current limit value ITL. FIG. 7A shows the transition of the currents I1 to I3 of the respective energy storage banks 20A to 20C, and FIG. 7B shows the transition of the current limit value ITL of the energy storage system S1. The current I3 of the energy storage bank 20C is greater than the currents I1 and 12 for a period of until about 35 seconds have elapsed from the start of discharge. However, the current I3 is controlled to the current target value of the energy storage bank 20C, i.e., 50 A, and an excess of the current of the current I3 is resolved. In a period thereafter, although the magnitude relationship of the currents I1 to I3 of the energy storage banks 20A to 20C is reversed, an excess of the current is suppressed.

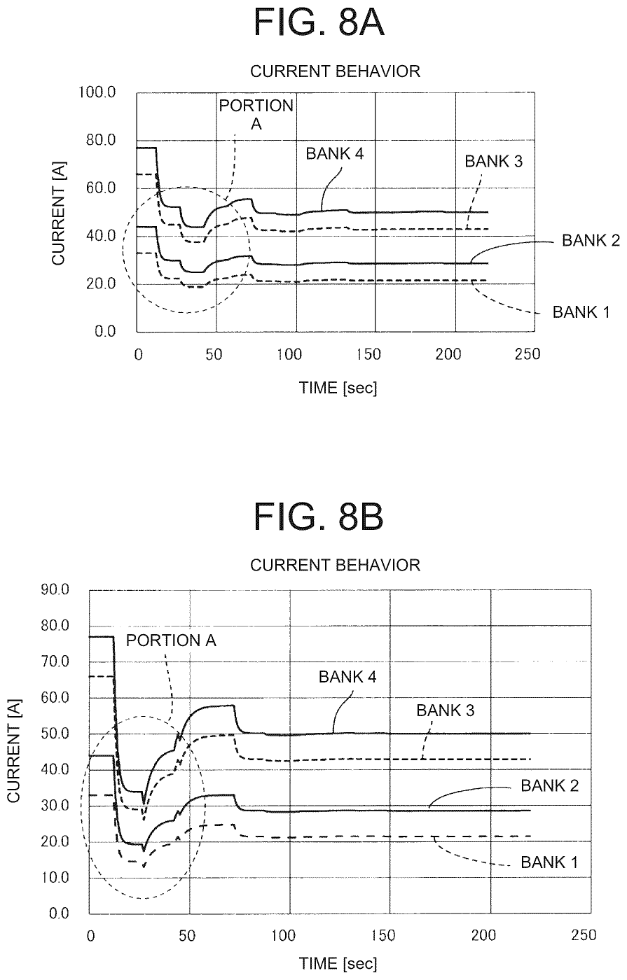

FIGS. 8A and 8B show the results of simulating a temporal transition of the current I of energy storage banks 1 to 4 in a case where the current limiting function is executed at the time of a discharge for an energy storage system including four banks. FIGS. 8A and 8B are different from each other in the method of calculating the current suppression value Isup. FIG. 8A shows a simulation result of a case where the current suppression value Isup according to Equation A of Embodiment 1 is used for the calculation of the current limit value Ilimit. FIG. 8B shows a simulation result of a case where the current suppression value Isup according to Equation F of Embodiment 3 is used.

In both of FIGS. 8A and 8B, the current I of the bank 4 exceeds the current target value of the energy storage bank, i.e., 50 A, for about several tens of seconds after a start of the simulation. However, after a lapse of about 70 seconds, the current I of the bank 4 is maintained at 50 A, which is the current target value of the energy storage bank. When FIGS. 8A and 8B are compared, as regards the behavior of the current I of the bank 4, an undershoot and an overshoot (portion A in the figures) that occur until the current converges to the target value of 50 A are more suppressed in FIG. 8A than in FIG. 8B, and a smooth response can be realized in FIG. 8A.

### 3. Description of Advantageous Effects

With this configuration, in the energy storage banks 20A to 20C, it is possible to suppress an excess of the current of the currents I1 to I3 with respect to the current target value Ino of the energy storage bank 20, whereby the energy storage system S1 can be operated safely.

### Embodiment 2

In Embodiment 1, the currents I1 to I3 [A] of the energy storage banks 20A to 20C are controlled. However, power P[W] of the energy storage banks 20A to 20C may be controlled instead of the current I. In this case, the bank management device 50 may calculate a power suppression value Psup and a power limit value Plimit by the following equations (D) and (E).

Psup=(previous value of Psup+Pno−Pnt)×(Pno/Pnt) Equation (D)

Plimit=Pno+Psup Equation (E)

In the above, Psup represents the power suppression value of the energy storage bank 20, Pno represents the power target value of the energy storage bank 20, Pnt represents the power measurement value of the energy storage bank 20, and Plimit represents the power limit value of the energy storage bank 20. When Psup>0 (i.e., when there is no excess of the power), it is assumed that Psup=0.

### Embodiment 3

Embodiment 3 is different from Embodiment 1 in the method of calculating a current suppression value Isup of an energy storage bank 20. Bank management devices 50A to 50C calculate the current suppression value Isup of the energy storage bank 20 by the following equation (F).

$$Isup = previous value of Isup + ( Ino - Int ) \times ( Ino / Int ) \qquad Equation ( F )$$

In the above, Isup represents the current suppression value of the energy storage bank 20, Ino represents the current target value of the energy storage bank 20, and Int represents the current measurement value of the energy storage bank 20.

Also by the calculation method of Equation (F), the current suppression value Isup of the energy storage bank 20 can be obtained similarly as in the calculation method of Equation (A).

### OTHER EMBODIMENTS

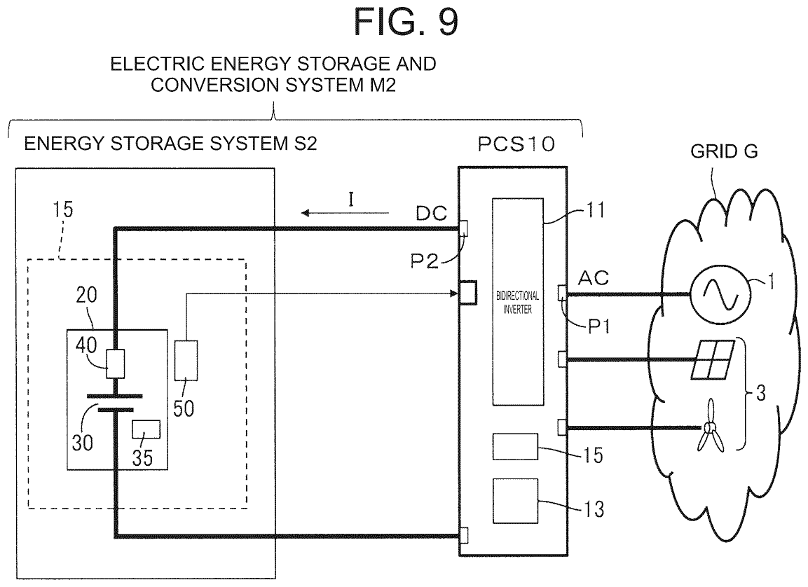

The present invention is not limited to the embodiments explained with reference to the above description and the drawings, and the technical scope of the present invention also incorporates therein, for example, the following embodiments.
(1) In the above embodiments, the present technique is applied to the energy storage system S1 including a plurality of banks. However, the present technique can also be applied to an energy storage system S2 including a single bank (see FIG. 9). That is, data on a current limit value Ilimit may be sent from an energy storage bank 20 to a power conditioner 10, and a current I of the energy storage bank 20 may be limited to exhibit a current limit value Ilimit or less by the power conditioner 10.
(2) The energy storage cell is not limited to a lithium-ion secondary battery, and may be other non-aqueous electrolyte secondary batteries or lead-acid batteries. A capacitor can also be used instead of the energy storage cell.
(3) In the above embodiments, although the bank management device 50 is provided separately from the energy storage bank 20, the bank management device 50 may be a part of the energy storage bank 20.
(4) In the above embodiments, the power conditioner 10 has been indicated as an example of the power conversion device. However, another device may be used as long as it is a bidirectional power converter (i.e., a power conversion instrument capable of charging and discharging the energy storage unit). For example, a DC-DC converter or the like may be used.
(5) In the above embodiments, as the calculation formula of the current suppression value Isup, Equation (A) and Equation (F) are indicated. As long as the current difference Ino-Int and the current ratio Ino/Int are used, the current suppression value Isup may be calculated from another equation.
(6) In the above embodiments, the current suppression value Isup and the current limit value Ilimit of each of the energy storage banks 20A to 20C are calculated in each of the bank management devices 50A to 50C. Alternatively, Ino and Int data may be transmitted from the bank management devices 50A to 50C to the integrated battery management device 100, and the integrated battery management device 100 may calculate the current suppression value Isup and the current limit value Ilimit of each of the energy storage banks 20A to 20C. That is, it suffices that the subject that arithmetically computes the current suppression value Isup and the current limit value Ilimit is a predetermined arithmetic device such as the bank management device 50 or the integrated battery management device 100.
(7) In the above embodiments, the integrated battery management device 100 calculates the current limit value ITL of the energy storage system S1 on the basis of the current limit values Ilimit1 to Ilimit3 of the respective energy storage banks 20A to 20C. Specifically, the current limit values Ilimit1 to Ilimit3 are compared with each other to determine the minimum current limit value Ilimit, and the current limit value ITL of the energy storage system S1 is calculated on the basis of the minimum current limit value Ilimit. As the method of determining the current limit value ITL of the energy storage system S1, another method may be employed as long as the method is based on the current limit values Ilimit1 to Ilimit3 of the respective energy storage banks 20A to 20C. For example, the determination may be made by using a mean value of the current limit values Ilimit1 to Ilimit3 of the energy storage banks 20A to 20C.
(8) In the above embodiments, although the current target value Ino of the energy storage bank 20 is calculated from the cell voltage Vc and the internal resistance R of the energy storage cell 31, the current target value Ino may be a predetermined fixed value.
(9) In Embodiment 1, the current limit value Ilimit of the energy storage bank 20 is calculated on the basis of a difference Ino-Int, which is the difference of the current measurement value Int from the current target value Ino of the energy storage bank 20, and a ratio Ino/Ino, which is the ratio of the current measurement value Int to the current target value Ino. Specifically, the calculation is performed by using Equation A and Equation B of Embodiment 1.

The current limit value Ilimit of the energy storage bank 20 may be calculated on the basis of the ratio Ino/Int of the current measurement value Int to the current target value Ino. Specifically, the calculation may be performed by using Equation (G) given below.

$$Ilimit = previous value of Ilimit \times ( Ino / Int ) \qquad Equation ( G )$$

In the above, Ilimt represents the current limit value of each of the energy storage banks 20, Ino represents the current target value of each of the energy storage banks 20, and Int represents the current measurement value of each of the energy storage banks 20. The initial value of Ilimt is the current target value Ino. The power limit value can also be calculated by a similar formula.

The current limit value Ilimit of the energy storage bank 20 can also be calculated from Equation H, instead of Equation G.

$$Ilimit = previous value of Ilimit \times ( minimum Ino / Int ) \qquad Equation ( H )$$

The minimum Ino/Int is a value smaller than 1, and is the minimum value of Ino/Int obtained by making a comparison between the energy storage banks. The power limit value can also be calculated by a similar formula.

In Equations G and H, the second term of the right-hand side is different. That is, the second term in Equation G is (Ino/Int), and the second term in Equation His (minimum Ino/Int). Equation G is a formula for calculating the current limit value Ilimit of each of the energy storage banks 20, and the second term (Ino/Int) represents a current ratio of each of the energy storage banks 20. Equation H is a formula for calculating the current limit value Ilimit that is common to the energy storage banks 20, and the second term (minimum Ino/Int) represents the minimum value of Ino/Int obtained by making a comparison between the energy storage banks. When Equation H is used, pieces of Ino/Int data of the respective energy storage banks 20A to 20C are transmitted from the bank management devices 50A to 50C to the integrated battery management device 100 and the integrated battery management device 100 obtains the minimum Ino/Int, and from the obtained minimum Ino/Int, the current limit value Ilimit that is common to the bank management devices 50A to 50C can be obtained. Further, the current limit value of the energy storage system S1 (ITL=Ilimit×N) can be obtained from the common current limit value Ilimit that has been obtained. In the above, N is the number of banks.
(10) In the energy storage system S1 of Embodiments 1 to 3, a selection switch for selecting whether or not the current limiting function should be executed for the integrated battery management device 100 (i.e., whether or not the current limit value ITL of the energy storage system S1 should be output to the power conditioner 10) may be provided. By providing the selection switch, the user can select whether or not to use the current limiting function.

1. An energy storage unit for an energy storage system, the energy storage unit comprising:
an energy storage bank which is connected to a power conversion device; and
a bank management device,
wherein the bank management device either:
calculates, based on a current target value and a current measurement value of the energy storage bank, a current limit value to limit an excess of a current with respect to the current target value; or
calculates, based on a power target value and a power measurement value of the energy storage bank, a power limit value to limit an excess of power with respect to the power target value.

2. The energy storage unit according to claim 1, wherein the bank management device either:
acquires at least the current measurement value at a predetermined cycle and updates the current limit value of the energy storage bank, or
acquires at least the power measurement value at a predetermined cycle and updates the power limit value of the energy storage bank.

3. The energy storage unit according to claim 1, wherein the bank management device either:
calculates the current limit value of the energy storage bank based on a difference of the current measurement value from the current target value of the energy storage bank and a ratio of the current measurement value to the current target value; or
calculates the power limit value of the energy storage bank based on a difference of the power measurement value from the power target value of the energy storage bank and a ratio of the power measurement value to the power target value.

4. The energy storage unit according to claim 3, wherein:
the bank management device either calculates the current limit value of the energy storage bank, or calculates the power limit value of the energy storage bank from equations which are:
$$Ylimit = Yno + Ysup ; and$$
$$Ysup = ( previous value of Ysup + Yno - Ynt ) \times ( Yno / Ynt ) ,$$
where Ylimit is one of the current limit value and the power limit value of the energy storage bank, Yno is one of the current target value and the power target value of the energy storage bank, Ysup is one of a current suppression value and a power suppression value of the energy storage bank, and Ynt is one of the current measurement value and the power measurement value of the energy storage bank.

5. The energy storage unit according to claim 1, wherein:
the bank management device either calculates the current limit value of the energy storage bank, or calculates the power limit value of the energy storage bank from an equation which is:
$$Ylimit = previous value of Ylimit \times ( Yno / Ynt ) ,$$
where Ylimit is one of the current limit value and the power limit value of the energy storage bank, Yno is one of the current target value and the power target value of the energy storage bank, and Ynt is one of the current measurement value and the power measurement value of each of energy storage banks including the energy storage bank.

6. An energy storage system which is connected to a power conversion device and stores electric energy, the energy storage system comprising:
a plurality of energy storage units; and
an integrated battery management device,
each of the energy storage units comprising:
an energy storage bank which is connected to the power conversion device; and
a bank management device which is provided to correspond to the energy storage bank, wherein
the integrated battery management device either:
acquires or calculates a current limit value of each of the energy storage banks from the bank management device, and calculates a current limit value of the energy storage system based on the current limit value of each of the energy storage banks; or
acquires or calculates a power limit value of each of the energy storage banks from the bank management device, and calculates a power limit value of the energy storage system based on the power limit value of each of the energy storage banks.

7. An electric energy storage and conversion system comprising:
a power conversion device; and
the energy storage system according to claim 6,
wherein the power conversion device either:
controls a current of the energy storage system to be less than or equal to a current limit value of the energy storage system; or
controls power of the energy storage system to be less than or equal to a power limit value of the energy storage system.
